(19) United States
(12) Patent Application Publication
(10) Pub. No.: US 2026/0052803 A1
(43) Pub. Date: Feb. 19, 2026

(54) GROWTH ENGINEERING OF MONOLITHIC AND AT LEAST RED EMITTING COLOR-TUNABLE LIGHT EMITTING DIODES AND METHODS THEREOF

(71) Applicant: Innovation Semiconductor, Inc., Rochester, NY (US)

(72) Inventors: Matthew T. HARTENSVELD, Wyckoff, NJ (US); Richard J. BROWN, Trumansburg, NY (US); James R. SHEALY, Hector, NY (US)

(21) Appl. No.: 19/295,130

(22) Filed: Aug. 8, 2025

Related U.S. Application Data
(60) Provisional application No. 63/682,571, filed on Aug. 13, 2024.
(60) Provisional application No. 63/741,708, filed on Jan. 3, 2025.

(51) Int. Cl. H10H 20/812; H10H 20/01; H10H 20/825

(52) U.S. Cl. CPC H10H 20/812; H10H 20/01335; H10H 20/825

(57) ABSTRACT

An LED system having color tunability in response to variations in driving current density is disclosed. In one example, the system includes a patterned dielectric layer, multiple quantum well (MQW) region, electron blocking layer (EBL), and p-type GaN layer. The EBL is deposited on the MQW region and structured such that the injection of holes into the MQW region is plane-specific. Plane-specific hole injection leads to targeted color emission tied to the level of band bending. The p-type GaN layer is deposited above the EBL and is doped to be a source of holes. For shorter wavelength emission, the p-GaN is designed such that there is adequate hole supply to lower layers of the MQW region. This selective injection of holes in the direction of various crystal planes, together with managed Indium concentration in the MQW region and an adequate supply of holes, enables smooth color tunability.

### CROSS-REFERENCE TO RELATED APPLICATION

This application claims the benefit of U.S. Provisional Application Ser. No. 63/741,708, filed Jan. 3, 2025, and 63/682,571, filed Aug. 13, 2024, all of which are incorporated by reference herein for all purposes.

### FIELD

This technology relates to architecture and fabrication of color tunable LEDs, LED elements, systems, and displays based on such LEDs.

### BACKGROUND

Solid state light sources and displays based on Light Emitting Diodes (LEDs) have been developed broadly across many lighting markets. In more recent years, ongoing interest in higher resolution LED displays, particularly those used in wearable and carriable consumer products, have led to efforts to increase total pixels and pixel density in a display to increase resolution and elevate LED performance in smaller form factor displays. These advances are most challenging regarding micro-LED displays of diameters below 200 microns for larger format applications such as monitors and televisions, and below 30 microns for displays of wearable or carriable products. More recently, displays for near eye applications such as virtual and augmented reality benefit from even smaller LEDs, where LED diameters can be in low single digit microns.

In most displays, the base light emitting unit, termed a pixel, has required three LEDs emitting red, green, and blue light such that, when driven in an appropriate relationship, they can produce a range of colors across the visible spectrum. However, there have been ongoing efforts to reduce the number of LEDs needed to create full color emission, as this would increase the ability to create higher resolution and higher pixel density displays, particularly in applications favoring micro-LED displays.

Efforts in recent years demonstrated some success in having individual LED light sources emit more than one color when driven across varying current densities. Such approaches include the physical stacking of light emitting structures, such as where different multiple quantum well (MQW) regions, each optimized for different colors, are grown in succession, or where the complete epi-layer structure of each of a red, green, and blue emitting LED is transferred to a single host wafer. Stacking approaches, however, suffer from light absorption and scattering due to the depth of emitting regions for each color, as well as structural inefficiencies such as insufficient LED spacing and additional switches (including transistors and wiring) required to power each LED. The stacking approach is further limited if more exotic or semiconductor hostile materials (such as Eu or Au) are used, making the scaled production of these devices challenging.

More recently, various approaches to achieve more than single color emission from an LED have been sought through crystal growth techniques. Initial works have explored the Indium content and emission from differing crystal planes to achieve different discrete emission wavelengths. However, these polychromatic emissions of different discreet colors were achieved in a simultaneous additive nature going from longer to shorter wavelengths based on current density such that the emissions mixed together, examples include the generation of white light. These polychromatic selective area growth (SAG) LEDs offer additive color but have not realized fully smoothly tunable color where one LED can emit multiple colors across a broad region of the visible spectrum to emit clear primary colors at different current densities and corresponding band bending. Nor do such existing works suggest any means to control the Indium concentration distribution or suggest any means to influence and vary current injection into the different crystal facets, which is critical to achieve smooth, full spectrum color tunability.

### SUMMARY

An exemplary embodiment of the present disclosure provides an LED system having color tunability in response to variations in driving current density. The system comprises one or more pixel elements that each comprise one or more LEDs each comprising: a first layer; a patterned dielectric layer formed over the first layer, wherein the patterned dielectric layer comprises an aperture; a second layer formed, via the aperture, over the first layer to provide a pattern along one surface of the second layer, wherein the pattern along the one surface of the second layer comprises protrusions in one or more shapes and sizes according to the aperture and with one or more spacing configurations to promote controlled color emissions in MQW layers of an MQW region, and wherein the second layer is actively doped; the MQW region formed over the one surface of the second layer, wherein each of the MQW layers is alloyed with a percentage of Indium to promote the controlled color emissions, wherein portions of the MQW layers that conform to sidewalls of the protrusions have a lower concentration of the alloyed percentage of Indium than other portions of the MQW layers; an electron blocking layer formed over the MQW region and is opposite in charge to the second layer, wherein the electron blocking layer is actively doped; and a third layer formed over the electron blocking layer and is opposite in charge to the second layer, wherein the third layer is actively doped. Portions of the MQW layers that conform to the sidewalls are capable of emitting in a blue wavelength range of 400 nm to 520 nm.

In an example, the one or more LEDs each further comprise a transition region within each MQW layer between each of the portions of the MQW layers conforming to the sidewalls of the protrusions and each of the other portions of the MQW layers and which transition region has a higher concentration of the alloyed percentage of Indium than the other portions of the MQW layers and where the alloyed percentage of Indium decreases with distance from the portions of the MQW layers that conform to the sidewalls of the protrusions.

In an example, the holes are injected at least laterally from the third layer into the transition region.

In an example, the first layer is actively doped.

In an example, the second layer comprises at least one crystal plane selected from the following five crystal planes: (0001), (11-22), (1-101), (11-20), or (1-100).

In an example, the electron blocking layer comprises AlGaN.

In an example, the third layer comprises p-type GaN.

In an example, the third layer further comprises at least one characteristic selected from the group consisting of a resistivity of less than 10 ohm·cm, a p-type doping concentration level from 1E16 to 1E21 per cubic centimeter, a thickness between 10 and 500 nm, and a combination thereof.

In an example, the one or more LEDs each further comprise a p-type InGaN layer formed over the third layer.

In an example, the one or more LEDs each further comprise a metal layer formed over the third layer.

Another exemplary embodiment of the present disclosure provides a method of operating an LED system having color tunability in response to variations in driving current density. The method comprises providing one or more pixel elements that each comprise one or more LEDs each comprising: a first layer; a patterned dielectric layer formed over the first layer, wherein the patterned dielectric layer comprises an aperture; a second layer formed, via the aperture, over the first layer to provide a pattern along one surface of the second layer, wherein the pattern along the one surface of the second layer comprises protrusions in one or more shapes and sizes according to the aperture and with one or more spacing configurations to promote controlled color emissions in MQW layers of an MQW region, and wherein the second layer is actively doped; the MQW region formed over the one surface of the second layer, wherein each of the MQW layers is alloyed with a percentage of Indium to promote the controlled color emissions, wherein portions of the MQW layers that conform to sidewalls of the protrusions have a lower concentration of the alloyed percentage of Indium than other portions of the MQW layers; an electron blocking layer formed over the MQW region and is opposite in charge to the second layer, wherein the electron blocking layer is actively doped; and a third layer formed over the electron blocking layer and is opposite in charge to the second layer, wherein the third layer is actively doped. The method further comprises applying a current to one of the LEDs such that holes from the third layer are injected into the portions of the MQW layers that conform to the sidewalls such that the portions of the MQW layers that conform to the sidewalls emit in a blue wavelength range of 400 nm to 520 nm.

In an example, the one or more LEDs each further comprise a transition region within each MQW layer between each of the portions of the MQW layers conforming to the sidewalls of the protrusions and each of the other portions of the MQW layers and which transition region has a higher concentration of the alloyed percentage of Indium than the other portions of the MQW layers and where the alloyed percentage of Indium decreases with distance from the portions of the MQW layers that conform to the sidewalls of the protrusions.

In an example, the method further comprises applying another current to the one of the LEDs such that holes are injected at least laterally from the third layer into the transition region such that the transition region emits in a red wavelength range of 580 nm to 700 nm, and wherein the another current is lower than the current applied to emit the blue wavelength.

In an example, the method further comprises applying a further current to the one of the LEDs such that holes are injected at least vertically from the third layer into portions of the MQW layers that are distanced from the transition region and portions of the MQW layers that conform to the sidewalls of the protrusions such that the distanced portions emit in a green wavelength range of 520 nm to 580 nm, and wherein the further current is lower than the current applied to emit the blue wavelength and higher than the another current applied to emit the red wavelength.

In an example, the first layer is actively doped.

In an example, the second layer comprises at least one crystal plane selected from the following five crystal planes: (0001), (11-22), (1-101), (11-20), or (1-100).

In an example, the electron blocking layer comprises AlGaN.

In an example, the third layer comprises p-type GaN.

In an example, the third layer further comprises at least one characteristic selected from the group consisting of a resistivity of less than 10 ohm·cm, a p-type doping concentration level from 1E16 to 1E21 per cubic centimeter, a thickness between 10 and 500 nm, and a combination thereof, whereby, upon the application of the current, the holes are able to be injected from the third layer into the portions of the MQW layers that conform to the sidewalls of the protrusions to achieve the emission in the blue wavelength range of 400 nm to 520 nm.

In an example, the one or more LEDs each further comprise a p-type InGaN layer formed over the third layer.

In an example, the one or more LEDs each further comprise a metal layer formed over the third layer.

Another exemplary embodiment of the present disclosure provides an LED system having color tunability in response to variations in driving current density. The system comprises: a current driver configured to drive variations in current density; and one or more pixel elements, coupled to the current driver, wherein each pixel element comprises one or more LEDs each comprising: a first layer; a patterned dielectric layer formed over the first layer, wherein the patterned dielectric layer comprises an aperture; a second layer formed, via the aperture, over the first layer to provide a pattern along one surface of the second layer, wherein the pattern along the one surface of the second layer comprises protrusions in one or more shapes and sizes according to the aperture and with one or more spacing configurations to promote controlled color emissions in MQW layers of an MQW region, and wherein the second layer is actively doped; the MQW region formed over the one surface of the second layer, wherein each of the MQW layers is alloyed with a percentage of Indium to promote the controlled color emissions, wherein portions of the MQW layers that conform to sidewalls of the protrusions have a lower concentration of the alloyed percentage of Indium than other portions of the MQW layers; an electron blocking layer formed over the MQW region and is opposite in charge to the second layer, wherein the electron blocking layer is actively doped; and a third layer formed over the electron blocking layer and is opposite in charge to the second layer, wherein the third layer is actively doped. Portions of the MQW layers that conform to the sidewalls are capable of emitting in a blue wavelength range of 400 nm to 520 nm.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF THE DRAWINGS

The foregoing summary, as well as the following detailed description, will be better understood when read in conjunction with the appended drawings. For the purpose of illustration only, there is shown in the drawings certain embodiments. It's understood, however, that the inventive concepts disclosed herein are not limited to the precise arrangements and instrumentalities shown in the figures. The detailed description will refer to the following drawings in which like numerals, where present, refer to like items.

FIG. 1A illustrates a cross-section of an exemplary color tunable single LED comprising a single structure selectively grown;

FIG. 1B illustrates a cross-sectional side view of an exemplary color tunable LED comprising multiple structures selectively grown;

FIG. 2 illustrates a plan view of different optimized example patterns of a dielectric on a surface prior to selective area growth;

FIG. 3A illustrates a cross-sectional side view of an exemplary color tunable single LED comprising a single structure selectively grown using a patterned dielectric (see, for example, FIG. 2), and with anode and cathode contacts;

FIG. 3B illustrates a cross-sectional side view of an exemplary color tunable LED comprising multiple structures selectively grown in series using a patterned dielectric (see, for example, FIG. 2), and with anode and cathode contacts.

### DETAILED DESCRIPTION

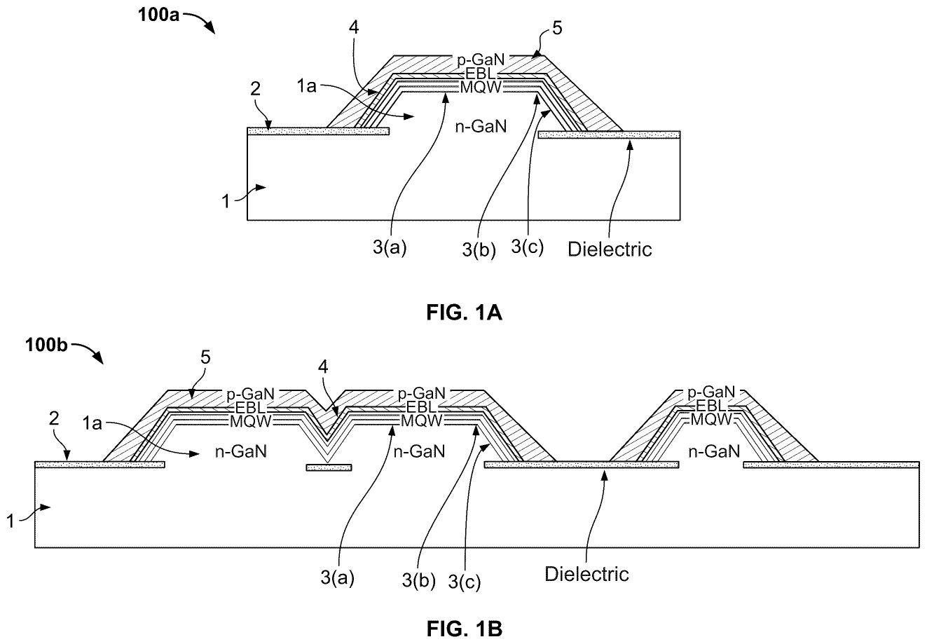

Examples of the color-tunable LED technology, as illustrated in FIGS. 1A-3B, provides several advantages including providing a full smoothly color-tunable LED system which can be effectively utilized in several different applications, such as displays (including VR or AR glasses/visors/headsets, etc.), commercial lighting, communications, and more.

Prior selective area growth efforts to generate emission of multiple colors from one LED demonstrated that certain architectures produced up to several discrete, limited wavelength emission bands that varied over a narrow range based on driving intensity. These can be viewed as “polychromatic” emissions, namely multiple emissions of constrained bandwidth that, in combination, produce aggregate color that is the additive combination of these emission bands.

They did not suggest or achieve, as is accomplished with the present disclosure, continuously variable, i.e., “tunable”, spectral emissions across the visible spectrum to enable producing full color from a single LED.

Compared to prior, polychromatic emission of light from light emitting diodes (LEDs), novel color tunability is achieved from LED architectures in accordance with the present invention produces tunable color, such that a selected range of unique colors, spanning from red to blue, are emitted by changes in driving current density and/or pulse width modulation, to generate colors across the visible light spectrum.

LEDs of the present disclosure can include a substrate (i.e., dielectric) on which is initially deposited one or more GaN layers to create an n-type region. This initial n-type region/layer or regions/layers may be undoped buffer layers or doped n-type layers. A patterned dielectric layer is deposited on the last deposited doped n-type layer, but in one embodiment may be deposited directly on a GaN growth-compatible substrate such as sapphire. Where deposited, the dielectric layer masks the underlying doped n-type layer or GaN growth-compatible surface from any additional n-type layer growth. An engineered n-type layer/protrusion is vertically grown on the previously deposited doped n-type layer or growth-compatible surface in areas not bearing the dielectric, to create architectural features that produce, post processing, laterally varying Indium concentration across each layer of the MQW region, which is necessary to enable color tunable emissions from each such MQW region layer. Examples of such engineered n-type layers/protrusions, discussed more fully below include unique growth features such as engineered adjacent sidewall planes, selected growth-related attributes (such as temperature, pressure, and precursor flow rates) and the particular shape and/or spacing of LED elements.

An MQW region is deposited over the adjacent underlying engineered n-type layer. As discussed more fully below, each layer in the MQW region can be optimized to emit a desired range of tunable color. Each quantum well (QW) deposited over the planar c-plane surface along the center of each engineered n-type protrusion acts as the near center point for emission and corresponding Indium concentration. The Indium concentration is varied based on the topography of the structure combined with the open space around the edges of the structure. The QW growth will proceed along each face of the engineered n-type surface at the same time. For the QW region grown on the sidewall surface, there is a lower concentration of Indium which is incorporated, leading to a shorter wavelength of emission. Meanwhile, the QW region grown on the c-plane near to the sidewall experiences reduced stress due to the nearby free surface and incorporates a higher concentration of Indium compared the same QW region located towards the center surface of the engineered n-type protrusion. Edits to the nominal Indium concentration as specified from the QW region grown in the center of the engineered n-type protrusion will modify the Indium included along the sidewall and that of the c-plane near the sidewalls, tailoring the total capable range of emission possible from the single QW. For example an increase in the concentration of Indium in the QW located on the center location of an engineered n-type protrusion correspondingly increases the Indium concentration along the sidewall and in the c-plane near to the sidewall edge, and vice-versa. In this way of modifying the nominal Indium concentration of a QW, each QW in the MQW region can be individually tailored to further enhance the total color range of emission of the LED.

An electron blocking layer (EBL) is deposited on the MQW region and structured such that the injection of holes into the MQW region is plane-specific. As will be described in more detail below, plane-specific hole injection leads to targeted color emission tied to the level of band bending. This selective injection of holes in the direction of various crystal planes, together with the managed Indium concentration, enables full color tunability.

A p-type GaN layer is deposited on the EBL and is doped to be a source of holes, with p-type doping concentrations from 1E16 to 1E21 per cubic centimeter. For shorter wavelength emission, the p-GaN is designed such that there is adequate hole supply to lower layers of the MQW region. Additional detail is provided below on the relationships involving the engineered n-type protrusions, the MQW region and the p-GaN layer that form the active device layers of a color tunable LED.

Spacing of these structures in the n-type region grown over a dielectric layer as described below, as well as their engineered architecture, including shapes and sizes, contribute to the efficiency and spectral characteristics in the resulting emission. Design aspects of the spacing and shape of the resulting structure are tools to tailor emission levels of each color. In one embodiment, a single LED pixel can optionally be comprised of multiple SAG LED structures to tailor the spectral nature and efficiency of more complex pixels. Examples can include partially merged structures which can enhance the green and shorter wavelength ranges, or smaller, more widely spaced structures which can enhance longer wavelength ranges. As one example, connecting multiple such structures (i.e., red-producing LEDs) in series is particularly beneficial to produce overall increased red emission intensity relative to green and blue emission.

Using these novel structural and layers, full color tunability can be achieved, such that the sidewall planes and structural spacing in the noted n-type GaN region/layer grown over the substrate/dielectric layer can be a technique for further laterally tuning the Indium concentration in the engineered n-GaN region/layer/protrusion to influence color tuning and resultant emission, while each quantum well may also be optimized for tunability in the vertical direction based on design and functionality of the EBL. One emission characteristic that can benefit from such vertical optimization is enhanced green emission.

Referring to FIG. 1A, an example selectively grown LED structure 100a is formed. Initially, a first layer of c-plane (0001) n-type GaN 1, comprising one or more intentionally or unintentionally doped regions, may be grown. The first layer of n-type GaN 1 may or may not be grown on a buffer region on either a host substrate (not shown), such as Si, SiC, AlN, or Al₂O₃ by way of example, or natively on a GaN substrate. Intentional doping concentrations, if used, may be between 1E16 and 1E21 per cubic centimeter.

A dielectric layer 2 is formed on the first n-GaN layer 1, and may be of SiO2, Si3N4, or SiON, by way of example. This dielectric layer 2 is then patterned and selectively etched to expose portions of the first n-GaN layer 1, or in other embodiments the underlying substrate (in this scenario, the n-GaN layer 1 may itself be replaced with a substrate comprising another material with no underlying additional substrate required), making the exposed areas available for further growth or formation of n-GaN material (i.e., extended n-GaN layer 1a). The thickness of the dielectric layer 2 may be between 1 nm and 1 μm. Alternatively, to avoid the need for selective etching, the dielectric layer 2 may be selectively deposited in a desired pattern to create exposed areas of the underlying n-type GaN layer 1 or GaN support surface (i.e., substrate) in a desired pattern for growth (or additional growth) of n-GaN material in areas unoccupied by the dielectric layer. Surface treatments may be done on the exposed n-type GaN layer 1 (or substrate) to remove any surface damage and contamination associated with deposition of the dielectric layer 2.

Selective area growth (SAG) is next performed to vertically grow (additional) n-type GaN to form or extend the n-GaN layer 1 in the areas free from the patterned dielectric material, to thereby form extended/growth/protrude n-GaN layer 1a. Such growth areas (i.e., extended n-GaN layer 1a) result from the chemical inertness of the dielectric layer 2. Growth conditions during this extended SAG such as temperature, gas ratios, pressure, and gas flow, combined with the pattern design and orientation, dictate the resulting structure(s) (i.e., extended n-GaN layer/region(s) 1a). However, the resulting structures can comprise at least one of five available crystal planes: (0001), (11-22), (1-101), (11-20), or (1-100). The result of the SAG forms/extends the n-type GaN 1 vertically from the substrate or previously deposited n-type GaN in n-GaN layer 1, through the dielectric layer 2 openings, with varying lateral growth of extended n-GaN layer 1a overlapping top portions of the dielectric layer 2, dependent on growth conditions. The overlapping growth of extended n-GaN layer 1a extending on top of the dielectric 2 is necessary to form the sidewall (i.e. the half or full V-groove shape) of the extended n-GaN layer 1a. The final structure of the extended n-GaN layer 1a impacts the subsequent LED growth and resulting color tunability. By way of example, extended n-GaN layer 1a having (1-101) planes promotes longer wavelength emission compared to extended n-GaN layer 1a with sidewalls of (1-100) planes or (11-20) planes which promote shorter wavelength emission.

Upon the extended n-GaN layer 1a created by SAG, the MQW regions 3a-3c are grown. The MQW regions 3a-3c comprise thin (e.g., 0.5 to 10 nm) thick InGaN layers formed in parallel, each followed by barriers of InGaN with lower Indium content, a GaN layer, or an AlGaN layer, each 0.5 to 30 nm thick, for example. Similarly, the MQW growth will only occur along the GaN facets and not on the dielectric layer 2. A moderate Indium concentration is selected for growth between 5% and 35%, for example. By way of example, the moderate Indium concentration exhibits green emission in the planar MQW region 3a away from any topography. Further optimization may be employed such that each individual quantum well has a unique content of Indium for the purposes of enhanced emission color and/or improved material quality. Simultaneous growth of the MQW region 3c along the sidewalls of the extended n-type GaN layer 1, such as the (1-101) plane, leads to lower Indium incorporation. The resulting Indium-poor incorporation of the MQW region 3c conforming to the sidewalls may be between 0 and 25%, for example. By way of example, the Indium-poor MQW regions 3c exhibits blue emission. The MQW region 3c which conforms to the sidewalls has a lower portion of Indium than the MQW region 3a conforming to the c-plane due to the Indium migration as well as surface differences between these planes. An Indium-rich MQW region 3b of transition (referred to herein as “transition region”) is formed between portions of the MQW region 3a that conforms to the c-plane away from any sidewalls and the MQW region 3c that conforms to the sidewalls. The Indium-rich MQW transition region 3b may have Indium content between 20 and 100%, for example, due to aspects such as Indium migration from the sidewalls as well as reduced compressive stress provided by the free surface during growth. The Indium content of the transition region 3b declines back to the expected planar MQW region 3a Indium content, away from the presence of the sidewalls. By way of example the Indium-rich MQW region 3b exhibits red emission. The proposed structure effectively modifies the Indium distribution laterally to form regions of low Indium content (MQW region 3c), moderate Indium content (MQW region 3a), and high Indium content (MQW region 3b) to emit across the full visible color spectrum.

To advantageously direct the charge carriers, an EBL 4 comprising AlGaN (e.g., p-type doped AlGaN) is utilized. The Aluminum content may be, for example, between 1 and 100%, the thickness of the AlGaN layer may be, for example, 0.5 to 300 nm, and the p-type doping concentration may be, for example, between 1E16 to 1E20 per cubic centimeter. In some advantageous embodiments, the EBL can be, for example, 16 nm thick and may have an Aluminum concentration of, for example, 5%. Similarly, the EBL 4 growth will simultaneously grow on the MQW regions 3a-3c, and not on the dielectric layer 2. AlGaN has a smaller lattice constant than GaN that leads to a polarization force at the interfaces of the AlGaN, proportional to the Aluminum content. The polarization force induces band bending at the EBL 4 creating an increased barrier height for hole injection in the direction perpendicular to the c-plane. The EBL 4 formed on the sidewalls though has a reduced, or possibly no, increased barrier height for holes due to the semi-polar or non-polar planes, respectively, that form. Beneficially, the EBL 4 with reduced barrier heights for holes along the sidewalls is leveraged to provide crystal orientation-specific injection of holes. Through the EBL 4 and the distribution of Indium in the MQW regions 3a-3c, full color-tunable emission can be enabled.

At low currents, and corresponding low level of band bending, holes are initially only able to be injected laterally from the sidewall-covering EBL 4 and populate the Indium-rich MQW transition region 3b to produce longer wavelength emission such as red light. With increased current density, and corresponding band bending, conventional vertical injection instead dominates from the c-plane EBL 4 into the MQW region 3a to produce moderate wavelength emission such as green light. Upon further increases in current density, and matching band bending, the MQW region 3c is populated with carriers alongside band bending from the MQW region 3a to together have a short emission wavelength such as blue light.

In other words, there are different pathways for current flow as we increase the applied voltage and respective current. As explained more fully, in the third doped region, it is critical that holes in this layer are injected into the MQW region 3b and/or 3c. Of particular importance, this occurs at low voltage and low current, where holes are laterally injected from the p-GaN layer 5 (discussed more fully below) and populate the indium-rich transition regions 3b which are the MQWs near the sidewalls but still parallel to the top surface. As the voltage is increased and the current is correspondingly raised, the initial energy barrier from the EBL 4 is reduced such that vertical injection becomes dominant, leading holes to instead more readily popular region 3a, where region 3a has less indium compared to region 3b leading to shorter wavelengths of emission such as green light instead of red light. Then, as the voltage is further increased and the current is further raised, the holes are once again injected laterally this time to the MQWs that conform to the sidewalls 3c. These MQWs (region 3c) have less indium than region 3a leading to even shorter blue wavelength emission. Coupled with this, the region 3a MQWs also begin to emit blue light instead of green.

It is noted that the EBL 4 has a slight barrier to holes which causes this initial lateral injection at lower voltages/current. As the voltage increases the barrier from the EBL 4 for holes is effectively eliminated. So basically, at the point 3c plays a role, the EBL has no influence for the lateral injection.

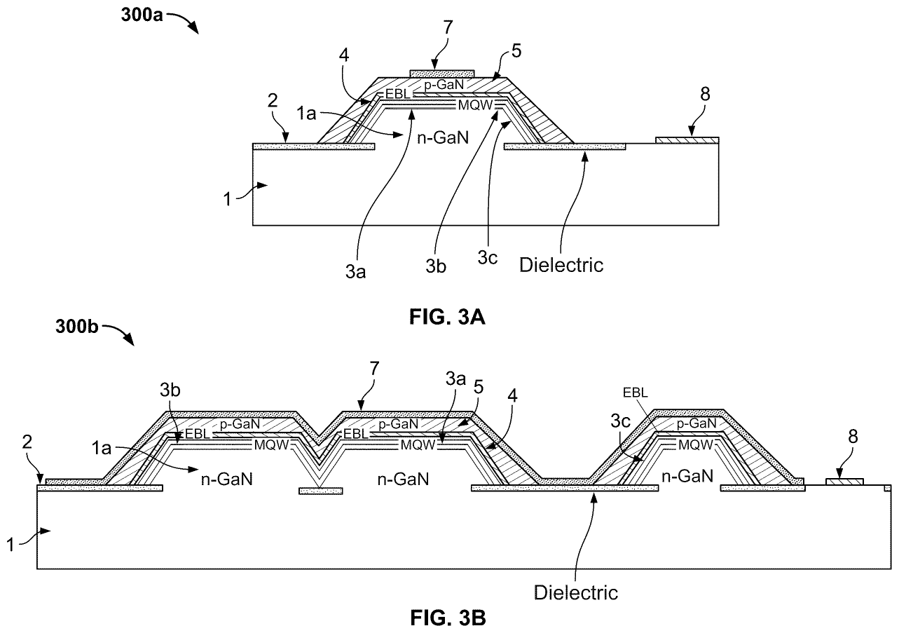

Upon the MQW regions 3a-3c, a p-type GaN layer 5 is conformally grown on the EBL 4 and substantially not (or not intentionally) on the dielectric layer 2. The p-type GaN layer 5 may comprise multiple doped layers with alloys of Indium and Aluminum to influence lateral hole concentrations and for purposes such as improved contact resistance and current direction. Importantly, the p-GaN layer 5 acts as the source of holes, with p-type doping concentrations from 1E16 to 1E21 per cubic centimeter. In practical devices employing the LED structure layers described herein, hole concentrations are more limited than that of electrons due to the higher ionization energy of many conventional p-type dopants in the GaN material system. For shorter wavelength emission, it is crucial to have the p-GaN layer 5 designed such that there is adequate hole supply to the lower MQW region 3c. Adequate hole supply here means that the transport of holes and corresponding current to the different crystal planes, such as the length of the sidewalls, is not limited by the resistivity of the p-GaN layer 5. To achieve adequate supply of holes, the resistivity of the p-GaN layer 5 can be engineered to have a resistivity of less than 10 ohm·cm. In cases where this is not readily feasible or to further lower overall resistance, the structure can further include a top low resistivity (less than 3 ohm·cm) current spreading layer such as a p-InGaN layer that is heavily doped (not shown) above the p-GaN layer 5. In other words, the resistance of the p-GaN layer 5 can often be too high (greater than 10 ohm·cm) such that there are few holes that are able to travel downwards to populate MQW region 3c. So the design of the LED structure is such that it is not limited by the resistance of the p-GaN layer 5. This can include having adequate doping and thickness of the p-GaN layer 5, or through the use of a low resistive current spreading layer such as the p-InGaN layer or a metal layer that is uniformly on top of the p-GaN layer 5. The thickness of p-GaN layer 5 may be increased (e.g., between 10 and 500 nm) to minimize increased resistivity due to factors such as scattering, the doping of the p-GaN layer 5 may be increased to provide more holes, and the use of an external top metal (see p-type contact 7 in FIG. 3B) for current spreading may be employed. The external top metal can be on top of the p-InGaN layer (if employed), or directly on top of the p-GaN layer 5.

By way of example, a p-type GaN layer 5 that is between 50-300 nm thick with a doping level of at least 1E19 per cubic centimeter at a resistivity of less than 9 ohm·cm can be employed with an additional top layer of p-InGaN that has 3-10% Indium and a doping level of at least 1E20 per cubic centimeter. Note that the thickness of the p-GaN layer 5 corresponds to the thickness perpendicular to the c-plane, where the resulting thickness along the semi-polar or non-polar sidewalls will be greater due to having an enhanced growth rate from the doping. The combination of the extended n-GaN layer 1a, MQW regions 3a-3c, EBL 4, and p-GaN layer 5, form the active device layers of a single fully color-tunable LED.

By way of another example, to achieve adequate hole supply when the additional top layer of p-InGaN is not employed, a p-type GaN layer 5 that is between 100 nm and 300 nm thick can have a doping level of at least 1.5E19 per cubic centimeter and a resistivity of less than 8 ohm·cm.

Referring to FIG. 1B, examples of multiple selectively grown protrusions/structures are together utilized to form a single fully color-tunable LED 100b. In some embodiments, a single fully color-tunable LED can comprise merged, initially independently selectively grown protrusions, for optimized color emission. These selectively grown protrusions follow the same types of growth techniques and practices as for isolated structures of FIG. 1A, though with slight differences due to the patterning of the dielectric layer 2. The design of the dielectric layer 2 with openings in proximity can cause the partial or full merging of the selectively grown protrusions. The partial merging can be advantageously applied in select embodiments, reducing the amount of long wavelength emission. The reduction of the longer wavelength emission is due to less Indium incorporation in the MQW transition region 3b around the partial merging due to less compressive strain relief and less MQW region 3c length on the sidewall for reduced Indium diffusion. In such structural cases, the EBL 4 and p-GaN layer 5 will also partially merge and share conductivity. The p-GaN layer 5 may also partially or fully planarize the area between the structures.

Engineering the dielectric layer 2 to have a smaller opening in such a LED structure would have the opposite impact as a partially merged structure. Due to a small device area, by way of example less than 30 μm, a larger fraction of the device exhibits compressive strain relief in the MQW regions 3a-3b. Additionally, if this structure is further spaced on one or more sides, even further Indium can be incorporated as Indium diffuses from the dielectric layer 2. The resulting selectively grown structure would be such that the entire spectrum is shifted to produce longer wavelength emission, in particular from the MQW regions 3a-3b.

Utilization of a multiple selectively grown structures in a color-tunable LED can be a beneficial technique to provide additional control over the emission spectra at various current densities. In certain embodiments, it is desired to leverage the spacing of multiple selectively grown structures to enhance longer wavelength emission at the cost of moderate and short wavelength emission.

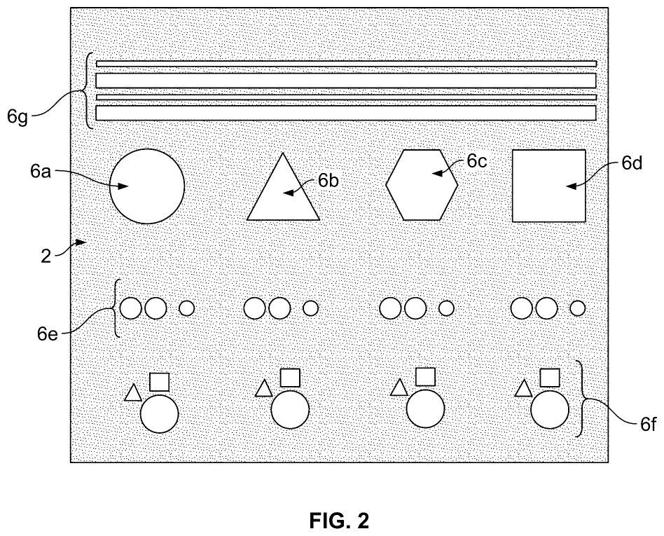

Referring to FIG. 2, formation of initial patterns in the dielectric layer 2 is a critical step for tailoring device results, as these translate to the pitch and size of the resulting grown LED structures. Isolated shape designs 6a-6d can be formed, comprising circle, triangles, hexagons, or squares, respectively, by way of example. Isolated shape designs 6a-6d will have the impact of increased Indium diffusion and incorporation into the structure compared with denser designs, due to the Indium on the dielectric layer 2 diffusing to these structures and being incorporated. The term “isolated” can be defined herein as having a spacing to the feature width of the device by over a factor of two, though can still be leveraged together with other structures to form arrays. Openings of the isolated shape designs may have sizes ranging, for example, from 100 nm to 500 μm.

Having multiple openings 6e patterned in the dielectric layer 2 in close proximity to each other can be utilized for growth of an ordered high-density array. Where the phrase “close proximity” is defined herein as a spacing to the feature width by less than a factor of 2. Each of the multiple openings 6e in the dielectric layer 2 may be, for example, from 100 nm to 500 μm. In cases where multiple selectively grown structures together form a complete LED, different shaped openings 6(f) can be fabricated. The same shape but different sizes or different shaped and different sized openings 6f may be fabricated to form these multiple selectively grown LEDs in order to modify the emission pattern. The spacing design of these different sizes and/or shaped openings 6f can be oriented in a 2-D array or the individual openings may advantageously be bunched together while the groupings may overall conform to a 2-D array. Compared to isolated features, those in close proximity compete for the available Indium, leading to comparatively shorter wavelength ranges.

In place of shapes, line openings 6g can also be patterned via the dielectric layer 2, such that one or more lines may later compose a fully color-tunable LED. Following selective area growth of the complete LED structure, perpendicular etches may be performed to turn the grown lines into separate LED rectangles or other suitable shapes. The etching to form line openings 6g may be, for example, as small as 100 nm wide, as large as 500 μm wide, spaced by 100 nm to 500 μm, and be as short as 1 μm or as long as 1 cm. The spacing of line openings 6g will have a key impact on the growth of the resulting selectively grown structures, similar to FIG. 1B, where close proximity lines will lead to short wavelengths, while small and/or isolated lines will lead to longer wavelengths. Orientation of the lines openings 6g during growth can influence resulting sidewalls formed as well as the amount of lateral growth. Line openings oriented parallel to the <10·0> can be advantageous for low lateral growth, meanwhile line openings oriented parallel to the <21·0> direction are preferred for higher lateral growth due to different sidewall crystal formations.

FIG. 3A illustrates an example where the metallization for an individual selectively grown color-tunable LED 300a forms an electrical contact. For the n-type GaN layer 1 contact, an opening can be made in the dielectric layer 2 followed by the selective or patterned deposition of a low work function metal or formation of a tunneling contact. By way of example, Ti—Al—Ni—Au can be utilized followed by an anneal to provide a low resistive n-GaN layer contact 8. Then, for the p-GaN layer 5, the p-type contact 7 can be directly formed by selective or patterned deposition of a high work function metal or formation of a tunneling contact, such as but not limited to Ni—Au (or a combination of Ni—Au with a layer or mixture of indium tin oxide) followed by an anneal. The p-type contact 7 may be selectively formed on just the c-plane surface or extended to all the p-GaN layer 5 surfaces including the sidewalls. Advantageously, coating the sidewalls with the p-type contact 7 can assist in current spreading in the p-GaN layer 5 and, specifically, hole injection into the MQW region 3c for shorter wavelength emission. The p-type contact 7 may be fully or partially transparent in areas (e.g., using indium tin oxide) for improved emission.

FIG. 3B shows an example where multiple selectively grown structures are together utilized to form a single fully color-tunable LED 300b, whether by forming distinct shapes 6e and 6f or lines 6g in the dielectric layer 2 prior to growth. As mentioned above, for the n-type GaN layer 1 contact 8, an opening can be made in the dielectric layer 2 followed by the selective or patterned deposition of a low work function metal or tunneling contact. By way of example, Ti—Al—Ni—Au can be utilized followed by an anneal to provide a low resistive n-GaN layer 1 contact 8. For the n-GaN layer 1 contact 8, as little as a single contact can be shared between the multiple selectively grown structures if the n-GaN layer 1 is sufficiently doped and the structures are in close proximity. Then, as mentioned above, for the p-GaN layer 5, the p-type contact 7 can be directly formed by selective or patterned deposition of a high work function metal or tunneling contact, such as but not limited to Ni—Au (or a combination of Ni—Au with a layer or mixture of indium tin oxide) followed by an anneal. The p-type contact 7 is shared between the multiple selectively grown structures on the p-GaN layer 5 surfaces including the sidewalls, as well as any dielectric layer 2 therebetween. In cases where not all the structures are partially or fully merged, sharing of the p-type contact 7 between the structures is a necessity, with the further benefit of enhanced current spreading for the p-type GaN layer 5 to aid in the injection of holes into the MQW region 3c for shorter wavelengths. The p-type contact 7 may be fully or partially transparent in areas (e.g., using indium tin oxide) for improved emission.

For both LED structures of FIGS. 3A and 3B, it is often desired to integrate the final fully color-tunable LED structure into a complete display system, where there are a number of ways this can be accomplished. By way of example, one such technique flips the complete structure of the color-tunable LED to bond to a prefabricated control wafer to integrate transistors with the display. Another example technique is through monolithic integration by pairing controlling transistors on top of or below the n-type GaN layer 1. Active, passive, or a custom current driver matrix array configurations may be created to control the fully color-tunable LEDs, with driving methods such as pulse width modulation or steady state current supply. In any such case, additional metallization, etch, dielectric deposition, and other such corresponding processes may be performed.

The active, passive, or custom current driver may have a matrix array configuration which can be realized in a variety of different ways. The current driver may comprise driver circuitry which can be fabricated on a Silicon wafer utilizing standard CMOS process technologies. The fabricated Silicon wafer containing the driver circuitry may be bonded to the whole color tunable LED wafer or individual arrays. The bonding approach can include techniques such as metal eutectic bonds, laser lift-off, Indium-based dots, interposers, and more. Alternatively, monolithic approaches can be leveraged for the driver circuitry such as those disclosed in U.S. Pat. No. 11,011,571 issued to Hartensveld et al. which integrate the driver circuitry directly out of the same GaN based materials. When leveraging the GaN based materials for both the color tunable LEDs as well as the driver circuitry, the need for external Silicon wafers or dies can be greatly reduced or eliminated entirely.

Regardless of a single structure or multiple selectively grown structures, the resultant device has the emission color changed based on current density, starting at longer wavelengths and going to shorter wavelengths. The resulting turn-on voltages for these fully color-tunable LEDs can also be lower than conventional c-plane LEDs due to the lateral injection of carriers in the techniques presented herein. Strategically, the structures are designed such that red emission occurs at low current density, green at moderate current density, and blue at high current density. By way of example, for an isolated 35 μm² color-tunable LED, the current density may range from ˜6×10⁻⁴ to ˜8×10⁻³ mA/μm² for red and blue, respectively.

As mentioned above, at low current density, the longer wavelength is emitting from the Indium-rich MQW transition regions 3b as holes are injected laterally due to the reduced barrier engineered through the EBL 4. With increasing current density, and corresponding band bending, vertical injection from the c-plane dominates leading to green emission from the MQW region 3a away from any sidewall. Upon further increasing the current density and band bending, the MQW region 3c that conforms to the sidewall populates, as well as having the bands bend in the MQW regions on the c-plane of regions 3a to produce blue light.

Increasing current density has the issue that current is generally proportional to light output, meaning the red emission will be dimmer than the green, and far dimmer than the blue. To balance the colors, control over the duty cycle for each color is to be engineered, such that blue is only on for a small fraction of the time during one period, green is on for a bit longer, and red may always be on for one period. Thereby, all the colors are referenced to the lowest current density emission of red. The discrepancy between the emission colors, however, can be partially mitigated through the techniques presented herein. To achieve emission of mixed colors such as white or purple, field sequential color is leveraged where the colors are appropriately weighted and swapped between two or more emission wavelengths to create the desired output. For example, operating points in yellow and blue, when weighted appropriately, can be rapidly swapped between each other to create the perception of white light. Utilization of these concepts enables the realization of fully color-tunable LED technologies.

Accordingly, as illustrated and described by way of the examples herein, this technology provides monolithic multi-color LEDs for use in displays (including VR or AR glasses/visors/headsets, etc.), commercial lighting, communications, and more. Monolithic integration of color-tunable LEDs without requiring any color converters reduces complexity, offers better performance, and lowers cost for many applications. Monolithic is defined for some examples herein as the same InGaN/GaN, III-N, material system used within the same wafer. In monolithic devices, the LEDs and transistors can even be fabricated on a single wafer. Examples of the claimed technology are able to provide monolithic color-tunable LEDs without Eu doping, growth of separate MQW regions, or excessively increased planar Indium %.

Although embodiments are described above with reference to a full color tunable LED system, the LED system described in any of the above embodiments may alternatively be a partial color tunable LED system. Such alternatives are considered to be within the spirit and scope of the present invention, and may therefore utilize the advantages of the configurations and embodiments described above.

Having thus described the basic concept of the technology, it will be rather apparent to those skilled in the art that the foregoing detailed disclosure is intended to be presented by way of example only and is not limiting. Various alterations, improvements, and modifications will occur and are intended to those skilled in the art, though not expressly stated herein. These alterations, improvements, and modifications are intended to be suggested hereby, and are within the spirit and scope of the technology. Additionally, the recited order of processing elements or sequences, or the use of numbers, letters, or other designations therefore, is not intended to limit the scope of the present invention.

What is claimed is:

1. An LED system for emitting in at least red wavelengths in response to variations in driving current density, the system comprising:
one or more pixel elements that each comprise one or more LEDs each comprising:
a first layer;
a patterned dielectric layer formed over the first layer, wherein the patterned dielectric layer comprises an aperture;
a second layer formed, via the aperture, over the first layer to provide a pattern along one surface of the second layer, wherein the pattern along the one surface of the second layer comprises protrusions in one or more shapes and with one or more spacing configurations to promote controlled color emissions in MQW layers of an MQW region, and wherein the second layer is actively doped;
the MQW region formed over the one surface of the second layer, wherein each of the MQW layers is alloyed with a percentage of Indium to promote the controlled color emissions, wherein portions of the MQW layers that conform to sidewalls of the protrusions have a lower concentration of the alloyed percentage of Indium than other portions of the MQW layers;
a transition region within each of the MQW layers located between the portions of the MQW layers that conform to the sidewalls of the protrusions and the other portions of the MQW layers;
an electron blocking layer formed over the MQW region and is opposite in charge to the second layer, wherein the electron blocking layer is actively doped; and
a third layer formed over the electron blocking layer and is opposite in charge to the second layer, wherein the third layer is actively doped;
wherein the transition region is capable of emitting in a red wavelength range of 580 nm to 700 nm.

2. The system of claim 1, wherein portions of the MQW layers that are distanced from the transition region and distanced from the portions of the MQW layers that conform to the sidewalls of the protrusions are capable of emitting in a green wavelength range of 520 nm to 580 nm.

3. The system of claim 1, wherein the transition region has a higher concentration of the alloyed percentage of Indium than the other portions of the MQW layers and where the alloyed percentage of Indium decreases with distance from the portions of the MQW layers that conform to the sidewalls of the protrusions.

4. The system of claim 1, wherein the LED system promotes substantially red wavelength emissions.

5. The system of claim 1, wherein the LED system promotes only red wavelength emissions.

6. A method of operating an LED system for emitting in at least red wavelengths in response to variations in driving current density, the method comprising:
providing one or more pixel elements that each comprise one or more LEDs each comprising:
a first layer;
a patterned dielectric layer formed over the first layer, wherein the patterned dielectric layer comprises an aperture;
a second layer formed, via the aperture, over the first layer to provide a pattern along one surface of the second layer, wherein the pattern along the one surface of the second layer comprises protrusions in one or more shapes and with one or more spacing configurations to promote controlled color emissions in MQW layers of an MQW region, and wherein the second layer is actively doped;
the MQW region formed over the one surface of the second layer, wherein each of the MQW layers is alloyed with a percentage of Indium to promote the controlled color emissions, wherein portions of the MQW layers that conform to sidewalls of the protrusions have a lower concentration of the alloyed percentage of Indium than other portions of the MQW layers;
a transition region within each of the MQW layers located between the portions of the MQW layers conforming to the sidewalls of the protrusions and the other portions of the MQW layers;
an electron blocking layer formed over the MQW region and is opposite in charge to the second layer, wherein the electron blocking layer is actively doped; and
a third layer formed over the electron blocking layer and is opposite in charge to the second layer, wherein the third layer is actively doped;
applying a current to the one of the LEDs such that holes are injected at least laterally from the third layer into the transition region such that the transition region emits in a red wavelength range of 580 nm to 700 nm.

7. The method of claim 6, wherein the method further comprises applying a further current to the one of the LEDs such that holes are injected at least vertically from the third layer into portions of the MQW layers that are distanced from the transition region and portions of the MQW layers that conform to the sidewalls of the protrusions such that the distanced portions emit in a green wavelength range of 520 nm to 580 nm, and wherein the further current is higher than the current applied to emit the red wavelength.

8. The method of claim 6, wherein the LED system has a higher concentration of the alloyed percentage of Indium than the other portions of the MQW layers and where the alloyed percentage of Indium decreases with distance from the portions of the MQW layers that conform to the sidewalls of the protrusions.

9. The method of claim 6, wherein the LED system promotes substantially red wavelength emissions.

10. The method of claim 6, wherein the LED system promotes only red wavelength emissions.
